(19) United States
(12) Patent Application Publication
(10) Pub. No.: US 2005/0018504 A1
(43) Pub. Date: Jan. 27, 2005

(54) Array of non volatile split-gate memory cells for avoiding parasitic programming and programming method thereof

(76) Inventors: Filippo Marinelli, Neuchatel (CH); Nadia Narabech, Neuchatel (CH)

Correspondence Address: SUGHRUE MION, PLLC, 2100 PENNSYLVANIA AVENUE, N.W., SUITE 800, WASHINGTON, DC, 20037, US

(21) Appl. No.: 10/896,911

(22) Filed: Jul. 23, 2004

(30) Foreign Application Priority Data
Jul. 23, 2003 (EP) 03016786.0

(51) Int. Cl. G11C 11/34

(52) U.S. Cl. 365/202

(57) ABSTRACT

There is disclosed an array (10) of split-gate non-volatile memory cells (24) supplied with power at a low voltage (V_{DD}) by a power supply (30), said cells being arranged in one or more rows and columns and electrically interconnected in groups to form one or more pages (12). The array comprises control logic (32) delivering a defined programming voltage (V_{PROG}) that is close or or substantially equal to the low power supply voltage that is applied to a control gate (245) of at least one cell (24A) that is to be programmed via a word control line (18) corresponding to that cell and blocking logic (36) delivering a first blocking voltage (V_{BLOC1}) that is greater than said low power supply voltage and is applied to the first regions (241) of the cells (24B) sharing the same word control line (18) as said cell that is to be programmed via a bit control line (22) corresponding to those cells.

This application claims priority from European Patent 03016786.0 filed Jul. 23, 2003, the entire disclosure of which is incorporated herein by reference.

### TECHNICAL FIELD

The present invention relates generally to an integrated circuit comprising an array of split-gate non-volatile FLASH EEPROM memory cells and using a page architecture for programming and erasing cells. The invention relates more particularly to the use of such memory array architectures for onboard applications in smart cards, where they replace conventional non-volatile memories.

The present invention also relates to a method of programming a memory cell of this kind of array.

### TECHNOLOGICAL BACKGROUND

Arrays of split-gate non-volatile memory cells arranged in one or more rows and columns and electrically interconnected in groups to form one or more pages are already known in the art. For example, U.S. Pat. No. 6,400,603, incorporated herein by reference, describes an array conforming to the general definition given above. FIG. 1 represents the architecture of an array 10 organised into eight columns each of 256 pages 12. To these eight columns there correspond eight columns of control circuits 14 each of 128 control circuits, with one control circuit per two pages. The different control signals, which are not described in detail here, enable conventional operations such as erasing a page or programming the cells of a page to be effected. There will nevertheless be noted amongst these signals row control lines 16 and 16b each connected to all control circuits 14 of the corresponding row. These row control lines 16 and 16b are for activating or deactivating a row control circuit 14. There will also be noted word control lines 18, source control lines 20 and bit control lines 22 for controlling each column of pages 12 and each column of control circuits 14.

FIG. 2 shows in detail one page 12 of the FIG. 1 array. In the example shown, each page 12 is formed by two rows of superposed memory cells 24.

FIG. 2A shows a memory cell 24 in more detail and to a larger scale. Each of these cells has a first region 241 called the drain, a second region 242 called the source and spaced from first region 241, a channel region 243 between first region 241 and second region 242, a floating gate 244, and a control gate 245.

These cells 24 contain binary information that is modified on programming or erasing the cell. On programming this kind of memory cell, the binary information that it contains may assume a first particular value, for example 0, as the result of hot electrons becoming trapped in floating gate 244 of the transistor. On erasing the cell, the binary information may assume a second particular value, for example 1, as the result of the Fowler-Nordheim tunnel effect, which allows a trapped electron to leave floating gate 244 without causing ionisation. To be able in particular to effect such programming operations, each cell receives first, second and third control signals that are respectively applied to control gate 245, second region 242 (i.e. the source) and first region 241 (i.e. the drain) of cell 24 to be programmed.

As previously mentioned, a page 12 is formed by a group of electrically interconnected cells 24. The cells of the same page may in particular be electrically interconnected by means of a source control line 20 interconnecting all sources 242 of the cells of a page. The second control signals are applied to sources 242 of the cells of the same page via these source control line 20.

The first control signals are applied to control gate 245 of at least one cell of a same page via word control lines 18 that preferably interconnect all cells 24 forming part of the same row on a page 12 (the rows are represented horizontally).

The third control signals are applied to drain 241 of each memory cell of the same column via bit control lines 22 which preferably connect all the memory cells of the pages forming part of the same column.

The following control signals are applied to program a particular cell 24 from all of the cells on a page 12:

for the cell that is to be programmed, for example cell FG16:

| | |
|---|---|
| 1^{st} control signal: | V_{PROG} |
| 2^{nd} control signal: | HV |
| 3^{rd} control signal: | I_{SINK} |

and for the other cells that are not to be programmed:

| | |
|---|---|
| 1^{st} control signal: | V_{PROG} or V_{SS} |
| 2^{nd} control signal: | HV |
| 3^{rd} control signal: | I_{SINK} or V_{DD} |

V_{PROG} represents the programming voltage applied via corresponding word control line 18 to control gate 245 of cell FG16 that is to be programmed. Consequently, all cells 24 of the page sharing same word control line 18, i.e. all cells FG1 to FG32, receive same control signal V_{PROG} at their control gate 245.

V_{SS} represents a reference voltage, for example the ground voltage, that is applied to control gate 245 of each of cells 24 of the page that does not share same word control line 18 as the cell that is to be programmed, i.e. all of cells FG33 to FG64.

I_{SINK} represents a bias current taken from drain 241 of cell FG16 to be programmed via bit control line 22 corresponding to that cell. Consequently, all cells 24 that form a column and share same bit control line 22 with the cell that is to be programmed, here cell FG48, have the same control signal applied to their drain.

V_{DD} represents the supply voltage of the memory that is applied to drain 241 of all the cells that do not share same bit control line 22, which normally prevents them from being programmed.

HV represents a high voltage, for example 12 volts, that is obtained from a charge pump comprising the appropriate number of amplifier stages. This high voltage is applied to source 242 of cell FG16 that is to be programmed via source control line 20 of the page containing that cell. As this source control line interconnects all sources 242 of cells 24 of the same page, high voltage HV is therefore also applied to the source of each of the cells of the page.

Note that, to program a cell, it is important for a current to be able to flow through channel 243 of that cell from source 242 to drain 241. On the other hand, to prevent unwanted programming problems, it is also important that no leakage current I_{F} flows through the channel of cells that are not to be programmed.

The type of memory described above is essentially intended for low-consumption applications, for example in a smart card or a mobile telephone. In Global System for Mobile communications (GSM) applications, for example, there are several standards relating in particular to the applicable supply voltage, which may be 1.8 V, 3V or 5V.

In the context of the present invention, it has been shown that for a low supply voltage, i.e. a supply voltage close to programming voltage V_{PROG}, the prior art memory described hereinabove suffers from unwanted or parasitic programming of cells on a same page as and sharing same word control line 18 as the cell that is to be programmed.

Considering FIGS. 2 and 2A again, when programming cell FG16, for example, cells FG1 to FG15 and cells FG17 to FG32 that all share same word control line 18 as cell FG16 receive programming voltage V_{PROG} at their control gate 245. In this case, the potential difference between source 242 and drain 241 of these regions is high and that between control gate 245 and drain 241 is low, the effect of which is that there is no strong resistance to the flow of leakage current I_{F} via channel 243. The combined result of these two effects is a high risk of unwanted or parasitic programming of cells 24 sharing same word control line 18 for a low supply voltage V_{DD} close to programming voltage V_{PROG}.

The problem of such unwanted programming arises not only from unwanted modification of the information contained in the memory but also from the necessity to limit the number of programming operations permitted before having to erase modified pages, which imposes a reduction of their size.

### SUMMARY OF THE INVENTION

A general goal of the present invention is therefore to propose a solution ensuring that information contained in the memory is highly reliable, combined with obtaining a reasonable service life of the memory.

Given this general goal, one particular object of the present invention is to ensure efficient programming of a particular cell using a low supply voltage without a high risk of unwanted programming of cells sharing electric connections with the cell to be programmed, in particular cells sharing the same word control line.

Thus the invention consists in an integrated circuit comprising a array of split-gate non-volatile memory cells of the type referred to hereinabove whose features are set out in claim 1.

The present invention also consists in a method of programming memory cells of this kind of array.

Advantageous embodiments of the present invention form the subject matter of dependent claims.

Thus it is proposed to provide the circuit with blocking logic delivering a blocking voltage that is higher than the low supply voltage and is applied to the drains of cells receiving the same first control signal as the cell to be programmed.

The invention also relates to an integrated circuit comprising voltage amplifier means connected to the blocking logic to deliver the blocking voltage that is higher than the low supply voltage.

For example, the voltage amplifier means may be a voltage doubler integrated into the array, a high-voltage supply of the charge pump type external to the array, or (and advantageously) at least one stage of a charge pump used to deliver the high voltage applied to the sources of the cells.

### BRIEF DESCRIPTION OF THE DRAWINGS

Other features and advantages of the present invention will become more clearly apparent on reading the following detailed description of embodiments of the invention specified by way of non-limiting example only and shown in the appended drawings, in which:

FIG. 1, already described, shows a page architecture of a prior art array of memory cells;

FIGS. 2 and 2A, already described, respectively show a page of the array from FIG. 1 in more detail and a split-gate memory cell from FIG. 2 to a larger scale;

FIGS. 3A and 3B show four adjacent cells and the signals applied to them in first and second programming modes, respectively; and

FIGS. 4A and 4B show the integration of amplifier means according to first and second embodiments of the invention.

### DESCRIPTION OF PREFERRED EMBODIMENTS

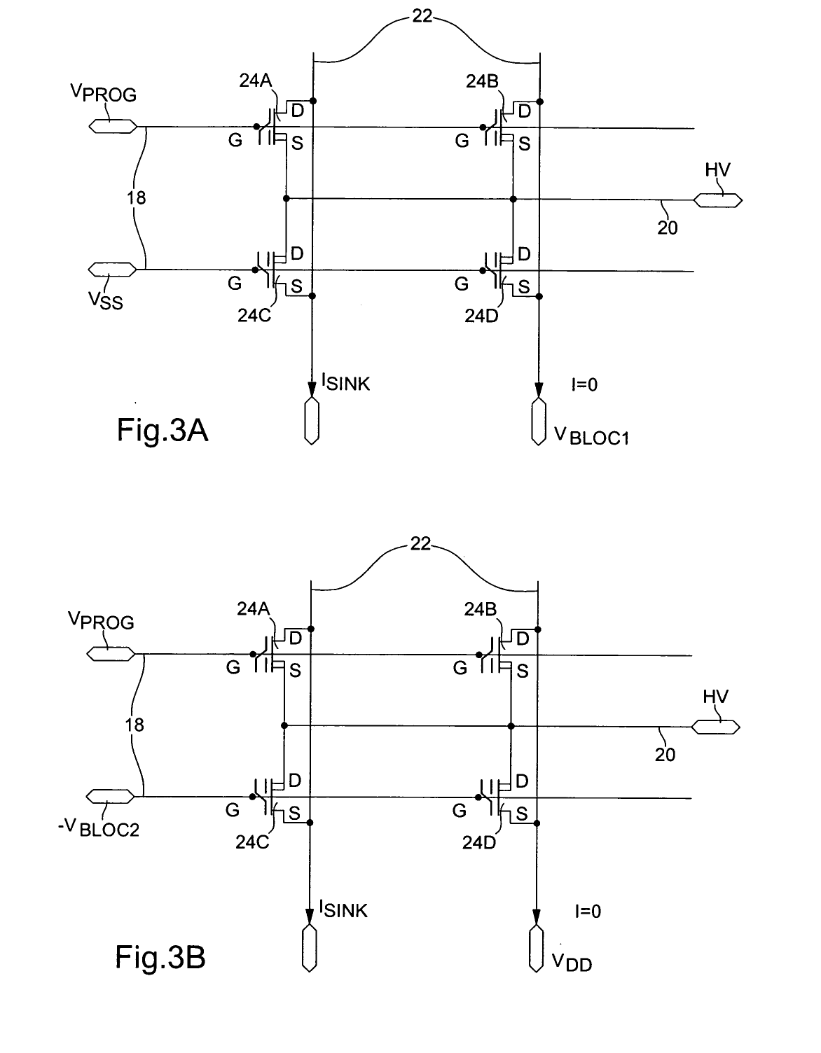

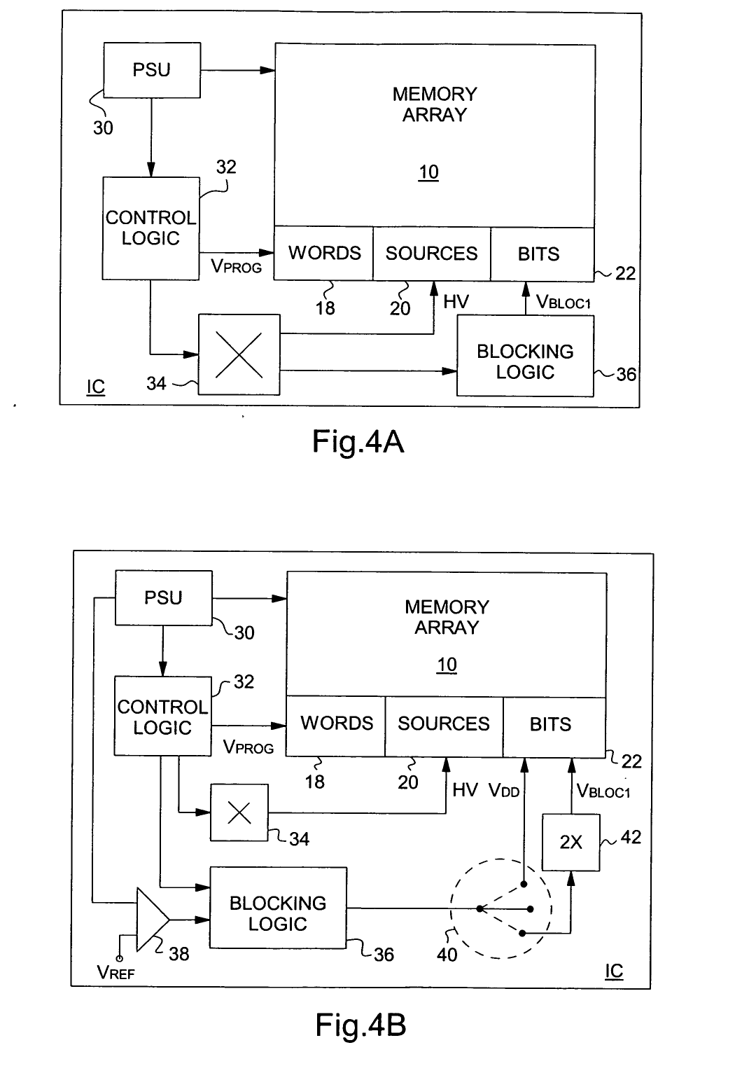

The remainder of the present description describes firstly programming modes according to the invention (see FIGS. 3A and 3B) and secondly the integration of the above kind of array into an integrated circuit (see FIGS. 4A and 4B).

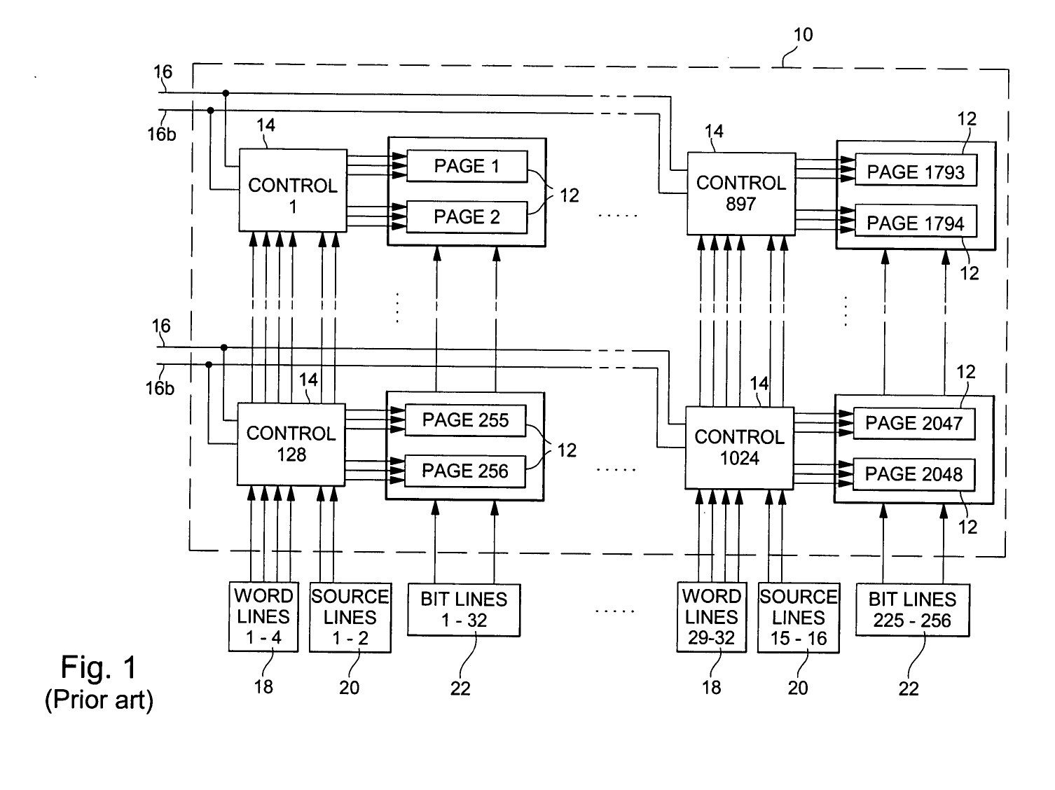

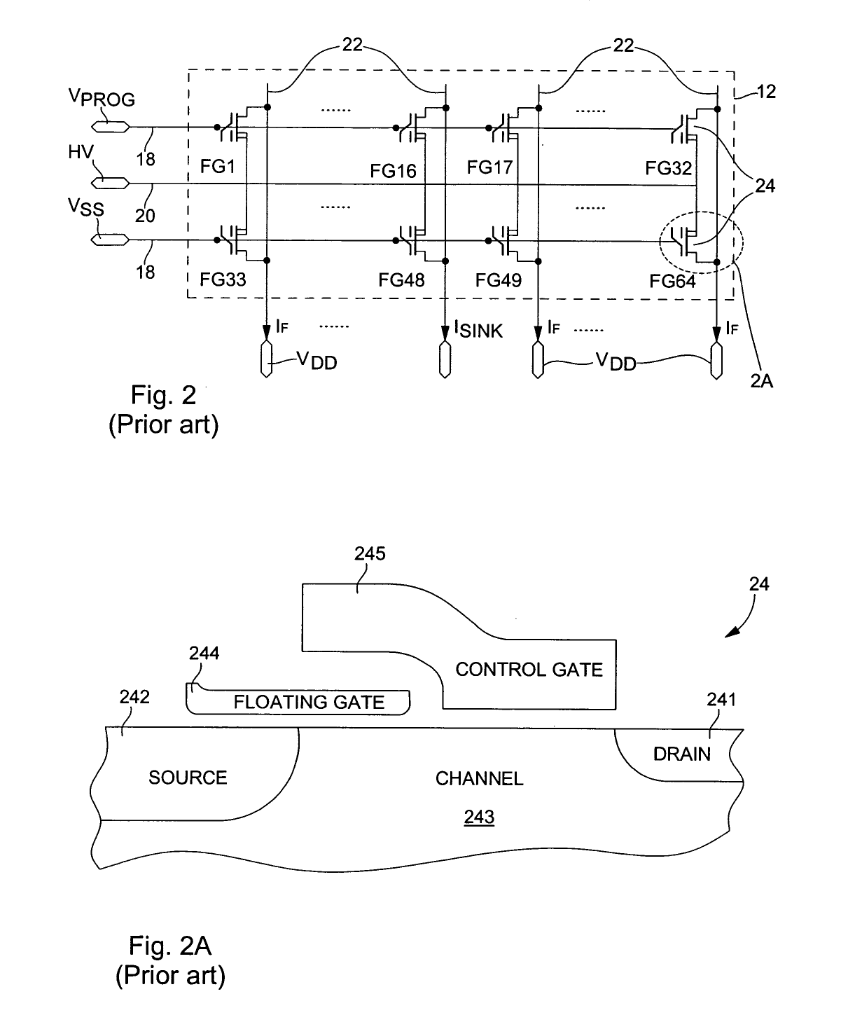

FIG. 3A depicts a first programming mode by way of non-limiting example and is a view to a larger scale of a portion of the memory array shown in FIG. 1, more particularly a page 12 shown in FIG. 2. This view to a larger scale shows four split-gate memory cells 24 of the same page. These cells 24A, 24B, 24C and 24D are similar to the cell shown in FIG. 2A. Each has a first region corresponding to its drain D, a second region corresponding to its source S, and a third region corresponding to its control gate G. The control gates G receive first control signals (V_{PROG} or V_{SS}) via word control lines 18. The sources S receive second control signals (HV) via a source control line 20. The drains D receive third control signals (I_{SINK} or V_{BLOC1}) via bit control lines 22.

In the example shown, the four cells 24A to 24D are interconnected in the following manner: The four cells belong to the same page and therefore share same source control line 20. Nevertheless, it is entirely feasible for these cells not to share physically the same source control line, but for each of the cells forming a page instead to receive a high voltage constituting a second control signal, independently of the other cells forming the same page and via separate source control lines. Cells 24A and 24B, respectively 24C and 24D, in the same row share same word control line 18. Cells 24A and 24C, respectively 24B and 24D, in the same column share same bit control line 22.

In the FIG. 3A example there is provision for programming cell 24A in a way that avoids unwanted programming of cell 24B, in particular when a low memory supply voltage is used. To program cell 24A, a programming voltage V_{PROG} slightly lower than or substantially equal to low supply voltage V_{DD} is applied to the control gate of cell 24A via word control line 18 corresponding to that cell. A high voltage HV is also applied to the source of cell 24A via the source control line 20 and a bias current I_{SINK} is taken from the drain D of cell 24A via bit control line 22 corresponding to that cell.

Cell 24B receives programming voltage V_{PROG} at its control gate because it shares same word control line 18 as cell 24A to be programmed, and it receives high voltage HV at its source because it shares same source control line 20 as cell 24A. On the other hand, the third control signal applied via bit control line 22 is free because cell 24B does not share same bit control line 22 as cell 24A that is to be programmed.

As has already been indicated in the context of the present invention, to prevent unwanted programming of cell 24B a first blocking voltage V_{BLOC1} greater than low supply voltage V_{DD} of the memory is applied to the drain of cell 24B via bit control line 22 corresponding to cell 24B. This first blocking voltage V_{BLOC1} is advantageously at least twice low supply voltage V_{DD}. There is therefore an extremely low probability of a conductive channel forming between the first and second regions (drain and source) of cell 24B and thus no significant leakage current I_{F} is able to flow through this channel to program the cell unintentionally.

It will be noted that cells 24C and 24D have their respective control gates connected to same word control line 18 and that the latter is different from the word control line connected to the control gate of cell 24A that is to be programmed. It is therefore possible to apply a first control signal in the form of a reference voltage V_{SS}, such as the ground voltage, for example, thus ensuring no programming of these cells.

FIG. 3B shows, also by way of example, the same enlarged view as FIG. 3A but now in relation to a second programming mode. The reference numbers are the same as those used in FIG. 3A. In the context of the present invention, another solution for preventing unwanted programming of cells sharing same word control line 18 as the cell or cells to be programmed consists in reducing programming voltage V_{PROG} of cell 24A that is to be programmed so that programming voltage V_{PROG} is clearly less than low memory supply voltage V_{DD}. It should nevertheless be noted that this programming voltage must remain sufficiently high to render conductive the channel of the cell that is to be programmed. Consequently, bias current I_{SINK} taken from the drain of cell 24A that is to be programmed via bit control line 22 leads to a reduced voltage at drain 241 of cell 24C which increases the potential difference between source 242 and drain 241 of cell 24C, thereby increasing its leakage current I_{F}. This results in an increased risk of unwanted programming of cells sharing same bit control line 22, i.e. of cell 24C in this example. To solve this problem, whilst still preventing unwanted programming of cells sharing same word control line 18 as the cell that is to be programmed, and differing in this respect from the first mode, there is provision for applying low supply voltage V_{DD} to the drains of cells 24B and 24D via bit control line 22 and for applying a negative second blocking voltage −V_{BLOC2} to word control line 18 of cells 24C and 24D. Thus neither the channel of cell 24B nor that of cell 24C has leakage current I_{F} flow through it.

FIG. 4A shows the integration of a memory array as previously defined into an integrated circuit IC conforming to a first embodiment of the invention. The integrated circuit is supplied with power at a low voltage V_{DD} by an external or internal power supply 30. The circuit includes memory array 10 as previously defined, i.e. the memory cells disposed in rows and in columns, plus cell control logic 32 delivering control signals via word control lines 18, source control lines 20 and bit control lines 22, respectively, as well as voltage amplifier means, for example a charge pump 34 for delivering a high voltage HV applied via source control line 20 to the sources of memory cells including a cell that is to be programmed. The circuit further comprises blocking logic 36 for delivering a blocking signal V_{BLOC1} that may be applied via bit control line 22 to the drains of cells sharing same word control line 18 as a cell that is to be programmed, in accordance with the first programming mode described above. Blocking logic 36 is connected to voltage amplifier means external or internal to the memory. There is advantageously provision for using high voltage HV supplied by charge pump 34, either by shunting the output voltage of a stage of the charge pump or by providing a voltage divider bridge, not shown, between the output of charge pump 34 and bit control lines 22 intended to receive blocking signal V_{BLOC1}.

With reference to the second programming mode described above, to obtain negative blocking signal −V_{BLOC2} that may be applied via corresponding word control line 18 to the control gates of cells sharing same bit line 22 as a cell that is to be programmed, it suffices to provide the integrated circuit IC with voltage inverter means, for example, these components not being shown in FIG. 4A.

FIG. 4B represents the integration of an array 10 as previously defined into an integrated circuit IC conforming to a second embodiment of the invention. Items common to FIG. 4A retain the same reference numbers. In this second embodiment, there is advantageously provision for supplying the integrated circuit IC with power at any supply voltage V_{DD}, preferably a standard voltage, and providing at least a predetermined low supply voltage V_{REF} referred to hereinafter as the reference voltage.

There are seen again array 10 of memory cells with its control logic 32 and its word control lines 18, source control lines 20 and bit control lines 22. As in the first embodiment, a charge pump 34 may be used to generate the high voltage HV applied to the sources of the cells of the same page, at least one of which cells is to be programmed.

When the second embodiment is used with the first programming mode, there are additionally provided means 38 for comparing supply voltage V_{DD} with the minimum supply voltage or reference voltage V_{REF} required for the integrated circuit IC to operate. If supply voltage V_{DD} is greater than reference voltage V_{REF}, activation means such as a switch 40, for example, are set to supply supply voltage V_{DD} direct to the drains of cells that are not to be programmed but share same word control line 18 as a cell that is to be programmed via bit control line 22 corresponding to those cells. If supply voltage V_{DD} is substantially equal to reference voltage V_{REF}, then activation means 40 are set so that supply voltage V_{DD} is amplified by voltage amplifier means, for example a voltage doubler 42 delivering at its output a blocking voltage V_{BLOC1} that is greater than supply voltage V_{DD} and is applied via corresponding bit control lines 22 to the drains of cells that are not to be programmed but share same word control line 18 as a cell that is to be programmed.

In the same manner as for the first embodiment, the second embodiment may simply be adapted to the second programming mode by replacing voltage doubler 42 with means for generating a negative blocking voltage −V_{BLOC2}, for example voltage inverter means, not shown.

It will be understood that diverse modifications and/or improvements that will be evident to the person skilled in the art may be made to the programming modes and embodiments described herein without departing from the scope of the invention as defined by the appended claims. This applies in particular to the voltage amplifier means used to obtain the first and second blocking voltages V_{BLOC1} and −V_{BLOC2} and to the architecture and interconnection of the split-gate memory cells forming the array. For example, blocking voltages V_{BLOC1} and −V_{BLOC2} may be supplied to the blocking means from a unit external to the integrated circuit containing the array of memory cells. Similarly, the high voltage HV applied to the sources of the memory cells via the source control line may be provided by a unit external to the integrated circuit.

It should finally be noted that the row and column concepts may be interchanged without changing the architecture of the memory array.

1. An integrated circuit comprising an array of split-gate non-volatile memory cells supplied with power at a low voltage by a power supply, said cells being arranged in one or more rows and columns and electrically interconnected in groups to form one or more pages, each of the cells having a first region, a second region spaced from the first region, a channel region between the first and second regions, a floating gate, and a control gate, the array being controlled in particular by:
first control lines each connected to the control gate of one or more cells of the same page;
second control lines each connected to the second region of all of the memory cells of the same page;
third control lines each connected to said first region of the memory cells of the same column; wherein
a control logic delivering a defined programming voltage that is close or substantially equal to the low power supply voltage that is applied to a control gate of at least one cell that is to be programmed via the first control line corresponding to that cell,
and wherein it further comprises:
a blocking logic delivering a first blocking voltage that is greater than said low power supply voltage and is applied to the first regions of the cells connected to the same first control line as said cell that is to be programmed via third control lines corresponding to those cells.

2. The integrated circuit according to claim 1, wherein the circuit further comprises voltage amplifier means connected to the blocking logic to deliver the first blocking voltage greater than the low power supply voltage.

3. The integrated circuit according to claim 2, wherein the amplifier means comprise a voltage doubler.

4. The integrated circuit according to claim 2, comprising a charge pump external to the array for delivering a high voltage that is applied to the second region of the cell that is to be programmed via the second control line corresponding to that cell, wherein the amplifier means comprise at least one stage of said charge pump.

5. The integrated circuit according to claim 2, supplied with power by a power supply at a power supply voltage that may be greater than a minimum reference voltage, wherein the blocking logic further comprises activation means for activating said amplifier means only for a power supply voltage substantially equal to the reference voltage.

6. The integrated circuit according to claim 1, wherein said first blocking voltage is supplied by a unit external to said circuit.

7. An integrated circuit comprising an array of split-gate non-volatile memory cells supplied with power by a power supply, said cells being arranged in one or more rows and columns and electrically interconnected in groups to form one or more pages, each of the cells having a first region, a second region spaced from the first region, a channel region between the first and second regions, a floating gate, and a control gate, the array being controlled in particular by:
first control lines each connected to the control gate of one or more cells of the same page;
second control lines each connected to the second region of all of the memory cells of the same page;
third control lines each connected to said first region of the memory cells of the same column; wherein
a control logic delivering a defined programming voltage that is less than the supply voltage that is applied to a control gate of at least one cell that is to be programmed via the first control line corresponding to that cell,
and wherein the circuit further comprises:
a blocking logic delivering a negative second blocking voltage that is applied to the control gate of the cell connected to the same third control line as said cell that is to be programmed via first control lines corresponding to those cells.

8. The integrated circuit according to claim 7, wherein said negative second blocking voltage is supplied by a unit external to said circuit.

9. A method of programming a memory cell of an array of the circuit according to claim 2, comprising in particular:
applying a defined programming voltage that is close or substantially equal to the low power supply voltage to the control gate of the cell that is to be programmed via the first control line corresponding to that cell;
amplifying said low power supply voltage to generate a first blocking voltage that is greater than said low power supply voltage; and
applying said first blocking voltage to the first regions of cells sharing the same first control line as said cell that is to be programmed via third control lines corresponding to those cells.

10. The method according to claim 9 of programming a memory cell, wherein the array may be supplied with power by a power supply having a power supply voltage that is greater than a minimum reference voltage, the method comprising a preliminary operation of activating said amplifier means only for a received power supply voltage that is substantially equal to the reference voltage.

11. A method of programming a memory cell of an array of the circuit according to claim 8, comprising in particular:
applying a defined programming voltage that is less than the supply voltage to the control gate of the cell that is to be programmed via the first control line corresponding to that cell;
generating a negative second blocking voltage;
applying this negative second blocking voltage to the control gates of the cells receiving a high voltage on their second control lines and sharing the same third control line as said cell that is to be programmed via first control lines corresponding to those cell; and
applying the low supply voltage to the cells receiving a high voltage on their second control lines sharing the same first control lines as said cell that is to be programmed via the third control line of those cells.
